(19) United States
(12) Patent Application Publication
(10) Pub. No.: US 2005/0250024 A1
(43) Pub. Date: Nov. 10, 2005

(54) Negative dye-containing curable composition, color filter and method of producing the same

(75) Inventor: Toru Fujimori, Shizuoka-ken (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/123,049

(22) Filed: May 6, 2005

(30) Foreign Application Priority Data
May 7, 2004 (JP) 2004-138893
Mar. 8, 2005 (JP) 2005-64638

(51) Int. Cl. G03F 9/00

(52) U.S. Cl. 430/7

(57) ABSTRACT

There are provided a negative dye-containing curable composition, comprising (A) an alkali-soluble binder, (B) an organic solvent-soluble dye, (C) a photopolymerization initiator and (D) a radical-polymerizable monomer, wherein: the ratio [y/x] of the mass of (D) the radical-polymerizable monomer [y] to the mass of (A) the alkali-soluble binder [x] is greater than or equal to 5.; also provided is a a color filter produced by using the negative dye-containing curable composition and a method of producing the color filter.

### CROSS-REFERENCE TO RELATED APPLICATION

This application claims priority under 35USC 119 from Japanese Patent Application Nos. 2004-138893 and 2005-64638, the disclosures of which are incorporated by reference herein.

### BACKGROUND OF THE INVENTION

1. Field of the Invention

The present invention relates to a negative dye-containing curable composition suitable for forming colored images constituting color filters used for liquid crystal display elements (CVD), solid state image pick-up elements (for example, CCD and CMOS) and the like, also to a color filter using the negative dye-containing curable composition and, further, to a method of producing the color filter.

2. Description of the Related Art

As methods of producing a color filter used for liquid crystal display elements and solid state image pick-up elements, a dyeing method, a printing method, an electrodepositing method and a pigment dispersion method are known.

In the pigment dispersion method, the color filter is produced by a photolithographic method using a colored radiation-sensitive composition prepared by dispersing a pigment in any one of various types of photosensitive compositions. The color filter produced by this method is stable with respect to light, heat and the like since the pigment is used. A high positional accuracy can be obtained in this method since patterning is performed by the photolithographic method and, accordingly, this method has widely been used as a method suitable for producing the color filter for a large screen and high fineness color display.

In a case in which the color filter is produced by the pigment dispersion method, the radiation-sensitive composition is first coated on a glass substrate by using, for example, a spin coater or a roll coater and, then, dried, to thereby form a coating film. Then, colored pixels are obtained by pattern-exposing and developing the thus-formed coating film. The color filter can be obtained by repeating such operation as described above by the number of different colors.

As for the pigment dispersion method, a method which uses a negative photosensitive composition comprising an alkali-soluble resin together with a photopolymerizable monomer and a photopolymerization initiator is proposed in each of, for example, JP-A Nos. 2-181704, 2-199403, 5-273411 and 7-140654.

On the other hand, the color filter for the solid state image pick-up element has been required to be finer in recent years. However, it is difficult to further improve resolution of the color filter according to the conventional pigment dispersion system. This is because the pigment dispersion method is not suitable for an application requiring a fine patterning such as the solid state image pick-up element since color unevenness occurs due to coarse pigment particles.

In order to solve the aforementioned problems, a technique using a dye instead of the pigment is proposed in JP-A No.6-75375. However, a problem arises that a dye-containing curable composition is generally inferior to a pigment-containing curable composition in various types of properties such as light fastness, heat resistance, solubility and coating evenness. Further, particularly in a case in which the dye-containing curable composition is used in forming the color filter for the solid state image pick-up element, since a film thickness as thin as 1.5 μm or less is required, it is necessary to incorporate a large amount of dye into the curable composition and such incorporation causes other problems of an insufficient adhesion with the substrate, an insufficient curing and bleaching of the dye in an exposed portion and, then, it becomes extremely difficult to attain good pattern forming properties.

### SUMMARY OF THE INVENTION

An object of the present invention is to provide a negative dye-containing curable composition suited for use as a dye, and in particular, to provide a negative dye-containing curable composition which is able to form patterns of rectangular contours with high sensitivity. Also, another object of the present invention is to provide a color filter, which is superior in pattern forming properties and has high cost performance, and a method of producing such a color filter.

Specific measures to solve the aforementioned problems are described below.

A first aspect of the invention is to provide negative dye-containing curable composition, comprising (A) an alkali-soluble binder, (B) an organic solvent-soluble dye, (C) a photopolymerization initiator and (D) a radical-polymerizable monomer, wherein:
the ratio [y/x] of the mass of (D) the radical-polymerizable monomer [y] to the mass of (A) the alkali-soluble binder [x] is greater than or equal to 5.

A second aspect of the invention is to provide color filter, produced by using a negative dye-containing curable composition comprising (A) an alkali-soluble binder, (B) an organic solvent-soluble dye, (C) a photopolymerization initiator and (D) a radical-polymerizable monomer, wherein:
the ratio [y/x] of the mass of (D) the radical-polymerizable monomer [y] to the mass of (A) the alkali-soluble binder [x] is greater than or equal to 5.

A third aspect of the invention is to provide method of producing a color filter, comprising:
applying the negative dye-containing curable composition as set forth in claim 1 onto a substrate;
exposing the applied negative dye-containing curable composition through a mask; and
developing the exposed negative dye-containing curable composition to form a pattern.

### DETAILED DESCRIPTION OF THE INVENTION

Hereinafter, a negative dye-containing curable composition of the present invention, a color filter to be producing by using the negative dye-containing curable composition and a method of producing the color filter will be described in detail.

Negative Dye-Containing Curable Composition

The present invention is a composition of a negative dye-containing curable composition comprising (A) an alkali-soluble binder, (B) an organic solvent-soluble dye, (C) a photopolymerization initiator and (D) a radical-polymerizable monomer, wherein: the ratio [y/x] of the mass of (D) the radical-polymerizable monomer [y] to the mass of (A) the alkali-soluble binder [x] is greater than or equal to 5. The negative dye-containing curable composition of the invention includes, as required, (E) an organic solvent.

Because the negative dye-containing curable composition of the present invention has a ratio of the mass of (D) radical-polymerizable monomer/the mass of (A) alkali-soluble binder≧5, the sensitivity is high, and further, the rectangularity of the pattern contours can be improved. In contrast, if the ratio of the mass of (D) the radical-polymerizable monomer/ the mass of (A) the alkali-soluble binder is less than 5 then the pattern contours significantly deteriorate, and pattern forming becomes impossible.

The exposure of the negative dye-containing curable composition of the present invention can be carried out by a proximity method, a mirror projection method, or a stepper method, however the stepper method (a reduction projection exposure method using a reduction projection exposure apparatus) for carrying out the photo-exposure is preferable. Regarding the stepper method, a pattern is formed by exposing whilst changing the exposing amount step-wise. Particularly by carrying out stepper exposure it is possible to realize one of the advantageous effects of the invention, good rectangularity of the pattern contours.

Also, for the exposure apparatus to use in the stepper exposure, for example, an i-line stepper (product name FPA-3000i5+; manufacturer Canon Inc.) and the like can be used.

In the invention, an important factor is the included solid content amounts of each of the above (A) to (D) in the solid content of the negative dye-containing curable composition of the invention. In the ratio (mass ratio [y/x]) of the mass of (D) radical-polymerizable monomer [y]/the mass of (A) the alkali-soluble binder [x], from the perspective of pattern forming property, y/x≧10 is preferable, y/x≧100 is more preferable, and y/x≧1000 is even more preferable. In particular if y/x≧100 then the advantageous effect of the invention can be dramatically improved. There is no particular upper limit to the value of the mass ratio (y/x) but it is good if y/x≦100000.

A total content of the (A) alkali-soluble binder to be used is, based on the total solid content (mass) of the total solid component, preferably in the range from 0.01% by mass to 70% by mass, and more preferably in the range of from 0.01% by mass to 50% by mass. When the content thereof is in the range of from 0.01% by mass to 70% by mass, resistance against an alkali developer is sufficient and a good pattern can be forming.

The content of (B) organic solvent-soluble dye included in the negative dye-containing curable composition of the present invention depends on the dye but, from the perspective of spectral reproducibility, the content is preferably in the range of from 0.5% by mass to 90% by mass of the total solid components, more preferably in the range of from 30% by mass to 90% by mass, and still more preferably in the range of from 40% by mass to 90% by mass. In particular, when the concentration included of the (B) organic solvent-soluble dye is high, then the effectiveness of setting the above mass ratio (y/x) to be greater than 5 is increased.

A total content of the (C) photopolymerization initiator to be used is, based on the total solid content (mass) of the (D) radical-polymerizable monomer, preferably in the range from 0.01 % by mass to 50% by mass, more preferably in the range of from 1% by mass to 30% by mass and, particularly preferably, in the range of from 1% by mass to 20% by mass. When the content thereof is in the range of from 0.01% by mass to 50% by mass, polymerization is facilitated and low film strength to be derived from a low molecular weight can be prevented.

Hereinafter, components to be contained in the negative dye-containing curable composition of the present invention are described.

A total content of the (D) radical-polymerizable monomer to be used is, based on the total solid content (mass) of the total solid component, preferably in the range from 5 % by mass to 80% by mass, and more preferably in the range of from 10% by mass to 70% by mass. When the content thereof is in the range of from 5% by mass to 80% by mass, a harding of a pattern and a dissolution of the non-image area is sufficient.

(A) Alkali-Soluble Binder

Hereinafter, the alkali-soluble binder will be described. The alkali-soluble binder according to the present invention is not particularly restricted, so long as it is soluble in an alkali. However, it is preferable that the alkali-soluble binder is selected from the viewpoint of heat resistance, development ability, availability and the like.

The alkali-soluble binder is preferably a linear organic polymer that is soluble in an organic solvent and developable with a weak alkali aqueous solution. Examples of the linear organic polymer include a polymer having a carboxylic acid on a side chain, such as a methacrylic acid copolymer, an acrylic acid copolymer, an itaconic acid copolymer, a crotonic acid copolymer, a maleic acid copolymer and a partially esterified maleic acid copolymer, described, for example, in JP-A No.59-44615, JP-B Nos. 54-34327, 58-12577 and 54-25957, and JP-A Nos. 59-53836 and 59-71048, and also, an acidic cellulose derivative having a carboxylic acid on a side chain is useful.

In addition to the foregoing, a polymer obtained by adding an acid anhydride to a polymer having a hydroxyl group, a polyhydroxystyrene resin, a polysiloxane resin, poly(2-hydroxyethyl (meth)acrylate), polyvinylpyrrolidone, polyethyleneoxide and polyvinyl alcohol are also useful.

A monomer having a hydrophilic group may be copolymerized, and examples thereof include alkoxyalkyl(meth)acrylate, hydroxyalkyl(meth)acrylate, glycerol(meth)acrylate, (meth)acrylamide, N-methylolacrylamide, secondary or tertiary alkylacrylamide, dialkylaminoalkyl(meth)acrylate, morpholine(meth)acrylate, N-vinylpyrrolidone, N-vinylcaprolactam, vinylimidazole, vinyltriazole, methyl(meth)acrylate, ethyl(meth)acrylate, branched or linear propyl(meth)acrylate, branched or linear butyl(meth)acrylate and phenoxyhydroxypropyl(meth)acrylate.

Furthermore, a monomer having a tetrahydrofurfuryl group, phosphoric acid, a phosphate ester, a quaternary ammonium salt, an ethyleneoxy chain, a propyleneoxy chain, sulfonic acid or a salt thereof, or a morpholinoethyl group is also useful as the monomer having a hydrophilic group.

Further, in order to improve a cross-linking efficiency, the alkali-soluble binder may have a polymerizable group in a side chain, and a polymer having an allyl group, a (meth)acrylic group or an allyloxy alkyl group in a side chain or the like is also useful as the alkali-soluble binder. Examples of such polymers each having the polymerizable group include KS Resist-106 (trade name; manufactured by Osaka Organic Chemical Industry Ltd.) and Cyclomer P Series (trade name; manufactured by Daicel Chemical Industries, Ltd.) which are commercially available. Still further, in order to increase strength of a cured film, alcohol-soluble nylon, a polyether of 2,2-bis-(4-hydroxyphenyl)-propane and epichlorohydrin and the like are also useful as the alkali-soluble binder according to the present invention.

Among these various kinds of alkali-soluble binders, a polyhydroxystyrene resin, a polysiloxane resin, an acrylic resin, an acrylamide resin and an acrylic/acrylamide copolymer resin are preferred from the standpoint of heat resistance, and an acrylic resin, an acrylamide resin and an acrylic/acrylamide copolymer resin are preferred from the standpoint of controllability of developing property.

Preferable examples of such acrylic resins as described above include a copolymer comprising a monomer selected from among benzyl(meth)acrylate, (meth)acrylic acid, hydroxyethyl(meth)acrylate and (meth)acrylic amide, as well as KS Resist-106 (trade name; manufactured by Osaka Organic Chemical Industry Ltd.) and Cyclomer P series (Daicel Chemical Industries, Ltd.) which are commercially available.

The alkali-soluble binder is preferably a polymer having a weight average molecular weight (a value in terms of polystyrene measured by using a GPC method) in the range of from 1000 to 2×10⁵, more preferably in the range of from 2000 to 1_33 10⁵ and, particularly preferably, in the range of from 5000 to 5×10⁴.

(B) Organic Solvent-Soluble Dye

The organic solvent-soluble dye according to the present invention is not particularly restricted, so long as it is soluble in an organic solvent. For example, a conventionally known dye for color filter can be used. Specific examples of such organic solvent-soluble dyes include coloring matters as described in JP-A Nos. 64-90403, 64-91102, 1-94301 and 6-11614; Japanese Patent No. 2592207; U.S. Pat. Nos. 4,808,501, 5,667,920 and 5,059,500; and JP-A Nos. 5-333207, 6-35183, 6-51115 and 6-194828. From the standpoint of a chemical structure, dyes of a triphenylmethane type, an anthraquinone type, a benzylidene type, an oxonol type, a cyanine type, a phenothiazine type, a pyrrolopyrazole azomethin type, a xanthene type, a phthalocyanine type, a benzopyran type, an indigo type and the like can be used. The organic solvent-soluble dyes are, particularly preferably, those of a pyrazoleazo type, an anilinoazo type, a pyrazolotriazoleazo type, a pyridoneazo type, an anthraquinone type and an anthrapyridone type.

Further, in a case of a resist system in which development is performed in water or an alkali, an acid dye or a derivative thereof can favorably be used from the viewpoint of completely removing at least one of the alkali-soluble binder and dye by the development. Other than these dyes, at least one of a direct dye, a basic dye, a mordant dye, an acid mordant dye, an azoic dye, a disperse dye, an oil-soluble dye, a food dye and derivatives thereof can also be usefully employed.

Acid Dye

The acid dye will be described below. The acid dye is not particularly restricted, so long as it is a dye having an acidic group of, for example, a sulfonic acid or a carboxylic acid, or a phenolic hydroxyl group. However, it is preferable to select the acid dye by taking into consideration all of required properties, such as solubility against an organic solvent or a developer, formability of a salt with a basic compound, light absorbance, an interaction with any one of other components in the curable composition, light fastness and heat resistance.

Although specific examples of such acid dyes are described below, the invention is not restricted to these examples. Examples of the acid dyes include:
Acid Black 24;
Acid Blue 1,7,9,15,83,86,90,103,108,113,120,249,;
Acid Green 1,3,5,9,16,50;
Acid Orange 7,8,10,12,50,51,52,63;
Acid Red 4,8,14,17,18,26,27,51,66,73,80,87,88,91,92,94,103,111,114,145,150,151;
Acid Violet 9,17,49;
Acid Yellow 1,7,9,11,17,23,34,36,38,40,65,72,76,135,228;
Direct Yellow 34;
Direct Orange 41,61,70;
Direct Violet 54;
Direct Blue 86,108,109,199;
Mordant Yellow 8,10,20;
Mordant Red 9,32;
Mordant Violet 2,41;
Mordant Blue 1,3;
Mordant Green 4;
Food Yellow 3;
Solvent Yellow 14;
Solvent Orange 2,7,15;
Solvent Red 49; and derivatives thereof.

As for the aforementioned derivatives of acid dyes, an inorganic salt of the acid dye having an acidic group of, for example, a sulfonic acid or a carboxylic acid, a salt of the acid dye with a nitrogen-containing compound, and a sulfonamide of the acid dye and the like can be used. The derivatives are not particularly restricted, so long as they are soluble in a solution of the curable composition. However, the acid dye is selected by taking into consideration all of required properties, such as solubility against an organic solvent or a developer, light absorbance, an interaction with any one of other components in the curable composition, light fastness and heat resistance.

The salt of the acid dye with the nitrogen-containing compound will be described below. Forming a salt between the acid dye and the nitrogen-containing compound may be effective for improving solubility (imparting solubility in an organic solvent) of the acid dye, heat resistance and light fastness.

The nitrogen-containing compound that forms a salt with the acid dye, and the nitrogen-containing compound that forms an amide bond with the acid dye will be described below.

The nitrogen-containing compound is selected taking into consideration all of the required properties such as solubility of the salt or the amide compound in the organic solvent or the developer, salt forming ability, light absorbance and a color value of the dye, an interaction between the nitrogen-containing compound and any one of other components in the curable composition, and heat resistance and light fastness as a coloring agent. A molecular weight of the nitrogen-containing compound is preferably as small as possible when the compound is selected considering only the light absorbance and color value. The molecular weight is preferably 300 or less, more preferably 280 or less and, particularly preferably, 250 or less.

A molar ratio (hereinafter, referred to also as “n”) of the nitrogen-containing compound to the acid dye in the salt between the acid dye and nitrogen-containing compound will be described below. The molar ratio n denotes a ratio of an acid dye molecule to an amine compound as a counter ion. The molar ratio n may be freely selected depending on a salt forming condition between the acid dye and the amine compound. Specifically, n is a value satisfying the relation of 0<n≦5 of the number of the functional groups in the acid of the acid dye in most practical cases, and may be selected considering all the required properties such as solubility in the organic solvent or the developer, salt forming ability, light absorbance, an interaction with any one of other components in the curable composition, light fastness and heat resistance. When n is selected from the viewpoint of only the light absorbance, n preferably satisfies the relation of 0<n≦4.5, more preferably 0<n≦4 and, particularly preferably, 0<n≦3.5.

Since the acid dye is prepared by incorporating an acid group into a structure thereof, it can be changed into a non-acid dye by changing a substituent thereof.

The acid dye may favorably act at the time of an alkali development but may sometimes be over-developed. For this account, when the acid dye is in the risk of being over-developed, the non-acid dye is sometimes favorably used.

For the dyes, in order to constitute the complementary colors of yellow, magenta, and cyan it is possible to use each of single dyes. However, in the case of constituting the primary colors of red, green and blue then combinations of two or more dyes are used. In the invention, it is preferable that primary colors are made up using combinations of two or more dyes.

(C) Photopolymerization Initiator

Next, the photopolymerization initiator according to the present invention will be described. The photopolymerization initiator is contained together with the radical-polymerizable monomer. The photopolymerization initiator is not particularly restricted, so long as it can polymerize the radical-polymerizable monomer. The photopolymerization initiator is preferably selected from the viewpoint of its properties, polymerization initiation efficiency, absorbing wavelength, availability, cost and the like.

Examples of such photopolymerization initiators include at least one active halogen compound selected from among halomethyl oxadiazole compounds and halomethyl-s-triazine compounds; 3-aryl substituted coumarin compounds; lophine dimers; benzophenone compounds; acetophenone compounds and derivatives thereof; cyclopentadiene-benzene-iron complexes and salts thereof; and oxime type compounds.

Examples of the active halogen compound as the halomethyloxadiazole compound include 2-halomethyl-5-vinyl-1,3,4-oxadiazole compound described in JP-B No. 57-6096, 2-trichloromethyl-5-styryl- 1,3,4-oxadiazole, 2-trichloromethyl-5-(p-cyanostyryl)-1,3,4-oxadiazole and 2-trichloromethyl-5-(p-methoxystyryl)-1,3,4-oxadiazole.

Examples of the active halogen compound as the halomethyl-s-triazine compound include a vinylhalomethyl-s-triazine compound described in JP-B No. 59-1281, and a 2-(naphtho-1-yl)-4,6-bishalomethyl-s-triazine compound and a 4-(p-aminophenyl)-2,6-dihalomethyl-s-triazine compound described in JP-A No. 53-133428.

Specific examples thereof include 2,4-bis(trichloromethyl)-6-p-methoxystyryl-s-triazine, 2,6-bis(trichloromethyl)-4-(3,4-methylenedioxyphenyl)-1,3,5-triazine, 2,6-bis(trichloromethyl)-4-(4-methoxyphenyl)-1,3,5-triazine, 2,4-bis(trichloromethyl)-6-(1 -p-dimethylaminophenyl-1,3-butadienyl)-s-triazine, 2-trichloromethyl-4-amino-6-p-methoxystyryl-s-triazine, 2-(naphtho-1-yl)-4,6-bistrichloromethyl-s-triazine, 2-(4-methoxynaphto-1-yl)-4,6-bistrichloromethyl-s-triazine, 2-(4-ethoxynaphtho-1-yl)-4,6-bistrichloromethyl-s-triazine, 2-(4-butoxynaphtho-1-yl)-4,6-bistrichloromethyl-s-triazine, 2-(4-(2-methoxyethyl)-naphto-1-4,6-bistrichloromethyl-s-triazine, 2-(4-(2-ethoxyethyl)-naphtho-1-yl)-4,6-bistrichloromethyl-s-triazine, 2-(4-(2-butoxyethyl)-naphtho-1-yl)-4,6-bistrichloromethyl-s-triazine, 2-(2-methoxynaphtho-2-yl)-4,6-bistrichloromethyl-s-triazine, 2-(6-methoxy-5-methylnaphtho-2-yl)-4,6-bistrichloromethyl-s-triazine, 2-(6-methoxynaphtho-2-yl)-4,6-bistrichloromethyl-s-triazine, 2-(5-methoxynaphtho-1-yl)-4,6-bistrichloromethyl-s-triazine, 2-(4,7-dimethoxynaphtho-1-yl)-4,6-bistrichloromethyl-s-triazine, 2-(6-ethoxynaphtho-2-yl)-4,6-bistrichloromethyl-s-triazine, 2-(4,5-dimethoxynaphtho-1-yl)-4,6-bistrichloromethyl-s-triazine, 4-(p-N,N-di(ethoxycarbonylmethyl)aminophenyl)-2,6-di(trichloromethyl)-s-triazine, 4-(o-methyl-p-N,N-di(ethoxycarbonylmethyl)aminophenyl)-2,6-di(trichloromethyl)-s-triazine, 4-(p-N,N-di(chloroethyl)aminophenyl)-2,6-di(trichloromethyl)-s-triazine, 4-(o-methyl-p-N,N-di(chloroethyl)aminophenyl)-2,6-di(trichloromethyl)-s-triazine, 4-(p-N-chloroethylaminophenyl)-2,6-di(trichloromethyl)-s-triazine, 4-(p-N-ethoxycabonylmethylaminophenyl)-2,6-di(trichloromethyl)-s-triazine, 4-(p-N,N-di(phenyl)aminophenyl)-2,6-di(trichloroemthyl)-s-triazine, 4-(p-N-chloroethylcarbonylaminophenyl)-2,6-di(trichloromethyl)-s-triazine, 4-(p-N-(p-methoxyphenyl)carbonylaminophenyl)-2,6-di(trichloromethyl)-s-triazine, 4-(m-N,N-di(ethoxycarbonylmethyl)aminophenyl)-2,6-di(trichloromethyl)-s-triazine, 4-(m-bromo-p-N,N-di(ethoxycarbonylmethyl)aminophenyl)-2,6-di(trichloromethyl)-s-triazine, 4-(m-chloro-p-N,N-di(ethoxycarbonylmethyl)aminophenyl)-2,6-di(trichloromethyl)-s-triazine, 4-(m-fluoro-p-N,N-di(ethoxycarbonylmethyl)aminophenyl)-2,6-di(trichloromethyl)-s-triazine, 4-(o-bromo-p-N,N-di(ethoxycarbonylmethyl)aminophenyl)-2,6-di(trichloromethyl)-s-triazine, 4-(o-chloro-p-N,N-di(ethoxycarbonylmethyl)aminophenyl)-2,6-di(trichloromethyl)-s-triazine, 4-(o-fluoro-p-N,N-di(ethoxycarbonylmethyl)aminophenyl-2,6-di(trichloromethyl)-s-triazine, 4-(o-bromo-p-N,N-di(chloroethyl)aminophenyl-2,6-di(trichloromethyl)-s-triazine, 4-(o-chloro-p-N,N-di(chloroethyl)aminophenyl)-2,6-di(trichloromethyl)-s-triazine, 4-(o-fluoro-p-N,N-di(chloroethyl)aminophenyl)-2,6-di(trichloromethyl)-s-triazine, 4-(m-bromo-p-N,N-di(chloroethyl)aminophenyl)-2,6-di(trichloromethyl)-s-triazine, 4-(m-chloro-p-N,N-di(chloroethyl)aminophenyl)-2,6-di(trichloromethyl)-s-triazine, 4-(m-fluoro-p-N,N-di(chloroethyl)aminophenyl)-2,6-di(trichloromethyl)-s-triazine, 4-(m-bromo-p-N-ethoxycarbonylmethylaminophenyl)-2,6-di(trichloromethyl)-s-triazine, 4-(m-chloro-p-N-ethoxycarbonylmethylaminophenyl)-2,6-di(trichloromethyl)-s-triazine, 4-(m-fluoro-p-N-ethoxycarbonylmethylaminophenyl)-2,6-di(trichloromethyl)-s-triazine, 4-(o-bromo-p-N-ethoxycarbonylmethylaminophenyl)-2,6-di(trichloromethyl)-s-triazine, 4-(o-chloro-p-N-ethoxycarbonylmethylaminophenyl)-2,6-di(trichloromethyl)-s-triazine, 4-(o-fluoro-p-N-ethoxycarbonylmethylaminophenyl)-2,6-di(trichloromethyl)-s-triazine, 4-(m-bromo-p-N-chloroethylaminophenyl)-2,6-di(trichloromethyl)-s-triazine, 4-(m-chloro-p-N-chloroethylaminophenyl)-2,6-di(trichloromethyl)-s-triazine, 4-(m-fluoro-p-N-chloroethylaminophenyl)-2,6-di(trichloromethyl)-s-triazine, 4-(o-bromo-p-N-chloroethylaminophenyl)-2,6-di(trichloromethyl)-s-triazine, 4-(o-chloro-p-N-chloroethylaminophenyl)-2,6-di(trichloromethyl)-s-triazine and 4-(o-fluoro-p-N-chloroethylaminophenyl)-2,6-di(trichloromethyl)-s-triazine.

Examples of other photopolymerization initiators which are usefully used and commercially available include TAZ-series manufactured by Midori Kagaku Co., Ltd. (for example, trade name: TAZ-107, TAZ-110, TAZ-104, TAZ-109, TAZ-140, TAZ-204, TAZ-113 and TAZ-123), T-series manufactured by PANCHIM Co. (for example, trade name: T-OMS, T-BMP, T-R and T-B), Irgacure series manufactured by Ciba Specialties Corp. (for example, trade name: Irgacure 651, Irgacure 184, Irgacure 500, Irgacure 1000, Irgacure 149, Irgacure 819 and Irgacure 261), Darocure series (for example, trade name: Darocure 1173), 4,4′-bis(diethylamino)-benzophenone, 2-(o-benzoyloxime)-1-[4-(phenylthio)phenyl]-1,2-octanedione, 1-(O-acetyloxime)-1-[9-ethyl-6-(2-methylbenzoyl)-9H-carbazole-3-yl]ethanone, 2-benzyl-2-dimethylamino-4- morphorinobutylophenone, 2,2-dimethoxy-2-phenylacetophenone, 2-(o-chlorophenyl)-4,5-diphenylimidazolyl dimer, a 2-(o-fluorophenyl)-4,5-diphenylimidazolyl dimer, a 2-(o-methoxyphenyl)-4,5-diphenylimidazolyl dimer, a 2-(p-methoxyphenyl)-4,5-diphenylimidazolyl dimer, a 2-(p-dimethoxyphenyl)-4,5-diphenylimidazolyl dimer, a 2-(2,4-dimethoxyphenyl)-4,5-diphenylimidazolyl dimer, a 2-(p-methylmercaptophenyl)-4,5-diphenylimidazolyl dimer and benzoin isopropyl ether.

Among these various kinds of photopolymerization initiators, oxime type compounds are preferred. For example, 2-(o-benzoyloxime)-1-[4-(phenylthio)phenyl]-1,2-octanedione and 1-(O-acetyloxime)-1-[9-ethyl-6-(2-methylbenzoyl)-9H-carbazole-3-yl]ethanone are preferred as the photopolymerization initiator.

The photopolymerization initiator may be used in combination with a sensitizer and a photo stabilizer.

Examples thereof include benzoin, benzoin methyl ether, 9-fluorenone, 2-chloro-9-fluorenone, 2-methyl-9-fluorenone, 9-anthrone, 2-bromo-9-anthrone, 2-ethyl-9-anthrone, 9,10-anthraquinone, 2-ethyl-9,10-anthraquinone, 2-t-butyl-9,10-anthraquinone, 2,6-dichloro-9,10-anthraquinone, xanthone, 2-methylxanthone, 2-methoxyxanthone, 2-ethoxyxanthone, thioxanthone, 2,4-diethylthioxanthone, acridone, 10-butyl-2-chloroacridone, benzyl, dibenzylacetone, p-(dimethylamino)phenyl styryl ketone, p-(dimethylamino)phenyl-p-methyl styryl ketone, benzophenone, p-(dimethylamino)benzophenone (or Michler's ketone), p-(diethylamino)benzophenone, benzoanthrone, a benzothiazole compound described in JP-B No. 51-48516, and TINUVIN 1130 and TINUVIN 400.

Other known photopolymerization initiators than such photopolymerization initiators as described above may be used in the negative dye-containing curable composition of the present invention.

Specific examples thereof include a vicinal polyketaldonyl compound described in U.S. Pat. No. 2,367,660, α-carbonyl compounds described in U.S. Pat. Nos. 2,367,661 and 2,367,670, an acyloin ether described in U.S. Pat. No. 2,448,828, an aromatic acyloin compound substituted with an α-hydrocarbon described in U.S. Pat. No. 2,722,512, a multinuclear quinone compound described in U.S. Pat. No. 2,951,758, a combination of a triaryllimidazole dimer and p-aminophenyl ketone described in U.S. Pat. No. 3,549,367, and a benzothiazole compound and a trihalomethyl-s-triazine compound described in JP-B No. 51-48516.

(D) Radical-Polymerizable Monomer

Next, the radical-polymerizable monomer according to the present invention will be described. The radical-polymerizable monomer according to the present invention is preferably a compound having at least one addition-polymerizable ethylenic double bond and a boiling point of 100° C. or more under normal pressure. The negative dye-containing curable composition of the present invention is constituted such that it has a negative by containing the radical-polymerizable monomer according to the present invention, together with a photopolymerization initiator to be described below and the like.

Examples of such radical-polymerizable monomers include monofunctional acrylates or methacrylates such as polyethylene glycol mono(meth)acrylate, polypropylene glycol mono(meth)acrylate, and phenoxyethyl(meth)acrylate; polyethylene glycol di(meth)acrylate, trimethylolethane tri(meth)acrylate, neopentylglycol di(meth)acrylate, pentaerythritol tri(meth)acrylate, pentaerythritol tetra(meth)acrylate, dipentaerythritol penta(meth)acrylate, dipentaerythritol hexa(meth)acrylate, hexanediol (meth)acrylate, trimethylolpropane tri(acryloyloxypropyl)ether, tri(acryloyloxyethyl)isocyanulate; (meth)acrylate compounds prepared after an addition reaction of ethylene oxide or propylene oxide to polyfunctional alcohols such as glycerine and trimethylolethane; urethane acrylates as described in JP-B Nos. 48-41708 and 50-6034, and JP-A No. 51-37193; polyester acrylates as described in JP-A No. 48-64183 and JP-B Nos. 49-43191 and 52-30490; a polyfunctional acrylate or methacrylate such as an epoxyacrylate which is a reaction product of an epoxy resin and (meth)acrylic acid; and mixtures thereof. Examples of the radical-polymerizable monomers further include compounds as described in Nihon Secchaku Kyokaishi (Journal of the Adhesion Society of Japan) Vol. 20, No. 7, pp.300 to 308 as a photocurable monomer and an oligomer.

Cross-Linking Agent

According to the present invention, it is possible to obtain a film, which has highly been cured by complementally using a cross-linking agent. The cross-linking agent will be described below.

The cross-linking agent capable of being used according to the present invention is not particularly restricted, so long as it can cure a film by a cross-linking reaction, and examples of such cross-linking agents include (a) an epoxy resin; (b) a melamine compound, a guanamine compound, a glycoluryl compound or a urea compound substituted with at least one substituent selected from among a methylol group, an alkoxymethyl group and an acyloxymethyl group; and (c) a phenol compound, a naphthol compound or a hydroxyanthrathene compound substituted with at least one substituent selected from among a methylol group, an alkoxymethyl group and an acyloxymethyl group. Among these cross-linking agents, a multifunctional epoxy resin is particularly preferably used as a cross-linking agent according to the present invention.

The epoxy resin (a) may be any compound that has an epoxy group and crosslinking property, and examples thereof include a divalent glycidyl group-containing low molecular weight compound, such as bisphenol A glycidyl ether, ethylene glycol diglycidyl ether, butanediol diglycidyl ether, hexanediol diglycidyl ether, dihydroxybiphenyl diglycidyl ether, diglycidyl phthalate and N,N-diglycidylaniline, a trivalent glycidyl group-containing low molecular weight compound, such as trimethylolpropane triglycidyl ether, trimethylolphenol triglycidyl ether and TrisP-PA (trisphenol P-PA) triglycidyl ether, a tetravalent glycidyl group-containing low molecular weight compound, such as pentaerythritol tetraglycidyl ether and tetramethylolbisphenol A tetraglycidyl ether, a polyvalent glycidyl group-containing low molecular weight compound, such as dipentaerythritol pentaglycidyl ether and dipentaerythritol hexaglycidyl ether, and a glycidyl group-containing polymer compound, such as polyglycidyl(meth)acrylate and a 1,2-epoxy-4-(2-oxiranyl)cyclohexane adduct of 2,2-bis(hydroxymethyl)-1-butanol.

The number of a methylol group, an alkoxymethyl group and an acyloxymethyl group contained in and substituted on the crosslinking agent (b) is generally from 2 to 6 in the case of the melamine compound and from 2 to 4 in the case of the glycoluril compound, the guanamine compound and the urea compound, and is preferably from 5 to 6 in the case of the melamine compound and from 3 to 4 in the case of the glycoluril compound, the guanamine compound and the urea compound.

Hereinafter, such melamine compound, guanamine compound, glycoluryl compound and urea compound as described in (b) may sometimes be referred to also as a methylol group-containing compound of the category (b), an alkoxymethyl group-containing compound of the category (b) or an acyloxymethyl group-containing compound of the category (b).

The methylol group-containing compound of the category (b) can be obtained by heating an alkoxymethyl group-containing compound in an alcohol in the presence of an acid catalyst, such as hydrochloric acid, sulfuric acid, nitric acid and methanesulfonic acid. The acyloxymethyl group-containing compound of the category (b) can be obtained by mixing and stirring a methylol group-containing compound with an acyl chloride in the presence of a basic catalyst.

Specific examples of the compounds of the category (b) having the aforementioned substituent are shown below.

Examples of the melamine compound include hexamethylolmelamine, hexamethoxymethylmelamine, a compound obtained by methoxymethylating from 1 to 5 methylol groups of hexamethylolmelamine or a mixture thereof, hexamethoxyethylmelamine, hexaacyloxymethylmelamine, and a compound obtained by acyloxymethlating from 1 to 5 methylol groups of hexamethylolmelamine or a mixture thereof.

Examples of the guanamine compound include tetramethylolguanamine, tetramethoxymethylguanamine, a compound obtained by methoxymethylating from 1 to 3 methylol groups of tetramethylolguanamine or a mixture thereof, tetramethoxyethylguanamine, tetraacyloxymethylguanamine, and a compound obtained by acyloxymethylating from 1 to 3 methylol groups of tetramethylolguanamine or a mixture thereof.

Examples of the glycoluril compound include tetramethylolglycoluril, tetramethoxymethylglycoluril, a compound obtained by methoxymethylating from 1 to 3 methylol groups of tetramethylolglycoluril or a mixture thereof, and a compound obtained by acyloxymethylating from 1 to 3 methylol groups of tetramethylolglycoluril or a mixture thereof.

Examples of the urea compound include tetramethylolurea, tetramethoxymethylurea, a compound obtained by methoxymethylating from 1 to 3 methylol groups of tetramethylolurea or a mixture thereof, and tetramethoxyethylurea.

The compounds of the category (b) may be used either each individually or in combinations of 2 or more types.

The cross-linking agent as described in (c), that is, a phenol compound, a naphthol compound or a hydroxyanthracene compound substituted with at least one group selected from a methylol group, an alkoxymethyl group and an acyloxymethyl group can suppress inter-mixing with a overcoat resist by forming cross-links by heating in a same manner as in (b) and further enhance film strength. Hereinafter, such compounds as described above may sometimes be referred to also as a methylol group-containing compound of the category (c), an alkoxymethyl group-containing compound of the category (c) or an acyloxymethyl group-containing compound of the category (c), respectively.

At least two methylol groups, acyloxymethyl groups or alkoxymethyl groups should be contained per one molecule of the cross-linking agent in (c). Compounds in which both the 2-position and 4-position of the phenol compound as a frame compound are substituted are preferable from the viewpoint of cross-linking ability by heating and preservation stability. Compounds in which both the ortho-position and para-position relative to the OH group of the naphthol compound or hydroxyanthracene compound as a frame compound are substituted are also preferable. The 3-position or 5-position of the phenol compound may be either substituted or unsubstituted.

Positions except the ortho-position relative to the OH group may be either substituted or unsubstituted in the naphthol compound.

The methylol group-containing compound of the category (c) may be obtained by using a compound having a hydrogen atom at the 2-or 4-position relative to the phenolic OH group as a starting material and, then, allowing the material to react with formalin in the presence of a base catalyst such as sodium hydroxide, potassium hydroxide, ammonia or tetraalkylammonium hydroxide.

The alkoxymethyl group-containing compound of the category (c) may be obtained by heating the methylol group-containing compound of the category (c) in an alcohol in the presence of an acid catalyst such as hydrochloric acid, sulfuric acid, nitric acid or methane sulfonic acid.

The acyloxymethyl group-containing compound of the category (c) may be obtained by allowing the methylol group-containing compound of the category (c) to react with an acyl chloride in the presence of a base catalyst.

Examples of the skeleton compound of the crosslinking agent of the category (c) include a phenol compound, a naphthol compound and a hydroxyanthracene compound, in which the o-positions and the p-positions of the phenolic hydroxyl group are unsubstituted, and examples thereof include phenol, isomers of cresol, 2,3-xylenol, 2,5-xylenol, 3,4-xylenol, 3,5-xylenol, a bisphenol compound, such as bisphenol A, 4,4′-bishydroxybiphenyl, TrisP-PA (produced by Honshu Chemical Industry Co., Ltd.), naphthol, dihydroxynaphthalene and 2,7-dihydroxyanthracene.

As specific examples of the crosslinking agent of the category (c), examples of the phenol compound include trimethylolphenol, tri(methoxymethyl)phenol, a compound obtained by methoxymethylating from 1 to 2 methylol groups of trimethylolphenol, trimethylol-3-cresol, tri(methoxymethyl)-3-cresol, a compound obtained by methoxymethylating from 1 to 2 methylol groups of trimethylol-3-cresol, a dimethylolcresol, such as 2,6-dimethylol-4-cresol, tetramethylolbisophenol A, tetramethoxymethylbisphenol A, a compound obtained by methoxymethlating from 1 to 3 methylol groups of tetramethylolbisphenol A, tetramethylol-4,4′-bishydroxybiphenyl, tetramethoxymethyl-4,4′-bishydroxybiphenyl, a hexamethylol compound of TrisP-PA, a hexamethoxymethyl compound of TrisP-PA, a compound obtained by methoxymethylating from 1 to 5 methylol groups of a hexamethylol compound of TrisP-PA, and bishydroxymethylnaphthalenediol.

Examples of the hydroxyanthracene compound include 1,6-dihydroxymethyl-2,7-dihydroxyanthracene, and examples of the acyloxymethyl group-containing compound include compounds obtained by acyloxymethylating a part or all of the methylol groups of the methylol group-containing compounds.

Preferable compounds among the aforementioned compounds are trimethylol phenol, bis hydroxymethyl-p-cresol, tetramethylol bisphenol A, and a hexamethylol form of TrisP-PA (manufactured by Honshu Chemical Industry Co., Ltd.) or a phenol compound in which methylol groups thereof are substituted with alkoxymethyl groups or another phenol compound in which methylol groups thereof are substituted with both methylol groups and alkoxymethyl groups.

The compounds of the category (c) may be used alone or in combinations.

Although A total content of the cross-linking agent to be used in the negative dye-containing curable composition depends on types of starting materials, from the standpoint of enhancing curability of the coating film, it is, based on the total solid content (mass) of the composition, preferably in the range of from 1% by mass to 70% by mass, more preferably in the range of from 5% by mass to 50% by mass and, particularly preferably in the range of from 7% by mass to 30% by mass.

Thermal Polymerization Inhibitor

A thermal polymerization inhibitor is preferably contained in the dye-containing curable composition of the present invention in addition to the aforementioned components. Examples thereof include hydroquinone, p-methoxypehnol, di-t-butyl-p-cresol, pyrogallol, t-butylcatechol, benzoquinone, 4,4′-thiobis(3-methyl-6-t-butylphenol), 2,2′-methylenebis(4-methyl-6-t-butylphenol) and 2-mercaptobeozimidazole as the thermal polymerization inhibitor.

(E) Organic Solvent

The negative dye-containing curable composition of the present invention contains at least one type of organic solvent. The organic solvent is fundamentally not particularly restricted, so long as it satisfies solubility of each component and coating ability of the negative dye-containing curable composition of the present invention. The organic solvent is preferably selected by taking into consideration particularly solubility of the dye and binder, coating ability and safety. When the negative dye-containing curable composition of the present invention is prepared, the composition preferably contains at least two types of organic solvents.

Preferred examples of the organic solvent include an ester compoud, such as an alkyl ester, e.g., ethyl acetate, n-butyl acetate, isobutyl acetate, amyl formate, isoamyl acetate, isobutyl acetate, butyl propionate, isopropyl butyrate, ethyl butyrate, butyl butyrate, an alkyl ester compound, methyl lactate, ethyl lactate, methyl oxyacetate, ethyl oxyacetate, butyl oxyacetate, methyl methoxyacetate, ethyl methoxyacetate, butyl methoxyacetate, methyl ethoxyacetate and ethyl ethoxyacetate;
a 3-oxypropionic acid alkyl ester, such as methyl 3-oxypropionate and ethyl 3-oxypropionate, for example, methyl 3-methoxypropionate, ethyl 3-methoxypropionate, methyl 3-ethoxypropionate and ethyl 3-ethoxypropionate, a 2-oxypropionic acid alkyl ester, such as methyl 2-oxypropionate, ethyl 2-oxypropionate and propyl 2-oxypropionate, for example, methyl 2-methoxypropionate, ethyl 2-methoxypropionate, propyl 2-methoxypropionate, methyl 2-ethoxypropionate, ethyl 2-ethoxypropionate, methyl 2-oxy-2-methylpropionate, ethyl 2-oxy-2-methylpropionate, methyl 2-methoxy-2-methylpropionate and ethyl 2-ethoxy-2-methylpropionate, methyl pyruvate, ethyl pyruvate, propyl pyruvate, methyl acetoacetate, ethyl acetoacetate, methyl 2-oxobutanoate and ethyl 2-oxobutanoate;
an ether compound such as diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol monomethyl ether, propylene glycol monomethyl ether acetate, propylene glycol monoethyl ether acetate and propylene glycol monopropyl ether acetate;
a ketone compound, such as methyl ethyl ketone, cyclohexanone, 2-heptanone and 3-heptanone, and an aromatic hydrocarbon compound, such as toluene and xylene.

As described above, from the standpoint of solubility of the dye and the alkali-soluble binder, an improvement of a coated face condition and the like, 2 or more types of these organic solvents may be mixed with one another. Particularly, a mixed solution constituted by 2 or more types of organic solvents selected from among methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, ethyl carbitol acetate, butyl carbitol acetate, propylene glycol methyl ether and propylene glycol methyl ether acetate is favorably used.

A content of the organic solvent according to the present invention is, based on total solid components, preferably in the range of from 5% by mass to 80% by mass, more preferably in the range of from 10% by mass to 50% by mass, from a view point of improving the coating property.

—Various Kinds of Additives—

In the dye-containing curable composition of the present invention, various kinds of additives may be added to the dye-containing curable composition of the present invention depending on necessity, such as a filler, a polymer compound other than those described in the foregoing, a surfactant, an adhesion accelerating agent, an antioxidant, an ultraviolet ray absorbing agent and an aggregation preventing agent. Furthermore, a discoloration preventing agent for the dye may also be added depending on necessity.

Examples of the additives include a filler, such as glass and alumina; a polymer compound other than the binder resin, such as polyvinyl alcohol, polyacrylic acid, polyethylene glycol monoalkyl ether and polyfluoroalkyl acrylate; a surfactant, such as a nonionic surfactant, a cationic surfactant and an anionic surfactant; an adhesion accelerating agent, such as vinyltrimethoxysilane, vinyltriethoxysilane, vinyltris(2-methoxyethoxy)silane, N-(2-amonoethyl)-3-aminopropyldimethylmethoxysilane, N-(2-aminoethyl)-3-aminopropyltrimethyoxysilane, 3-aminopropyltriethoxysilane, 3-glycidoxypropyltrimethoxysilane, 3-glycidoxypropylmethyldimethoxysilane, 2-(3,4-epoxycyclohexyl)ethyltrimethoxysilane, 3-chloropropylmethyldimethoxysilane, 3-chloropropyltrimethoxysilane, 3-methacryloxypropyltrimethoxysilane and 3-mercaptopropyltrimethoxysilane; an antioxidant, such as 2,2-thiobis(4-methyl-6-t-butylphenol) and 2,6-di-t-butylphenol; an ultraviolet ray absorbing agent, such as 2-(3-t-butyl-5-methyl-2-hydroxyphenyl)-5-chlorobenzotriazole and alkoxybenzophenone; and an aggregation preventing agent, such as sodium polyacrylate.

In order to accelerate the dissolution of the non-image area to an alkali solution to attain further improvement of the developing property of the dye-containing curable composition of the present invention, an organic carboxylic acid, preferably a low molecular weight organic carboxylic acid having a molecular weight of 1,000 or less, may be added to the composition.

Specific examples thereof include an aliphatic monocarboxylic acid, such as formic acid, acetic acid, propionic acid, butyric acid, valeric acid, pivalic acid, caproic acid, diethylacetic acid, enanthic acid and caprylic acid; an aliphatic dicarboxylic acid, such as oxalic acid, malonic acid, succinic acid, glutaric acid, adipic acid, pimelic acid, suberic acid, azelaic acid, sebacic acid, brassylic acid, methylmalonic acid, ethylmalonic acid, dimethylmalonic acid, methylsuccinic acid, tetramethylsuccinic acid and citraconic acid; an aliphatic tricarboxylic acid, such as tricarballylic acid, aconitic acid and camphoronic acid; an aromatic monocarboxylic acid, such as benzoic acid, toluic acid, cuminic acid, hemellitic acid and mesitylenic acid; an aromatic polycarboxylic acid, such as phthalic acid, isophthalic acid, terephthalic acid, trimellitic acid, trimesic acid, mellophanic acid and pyromellitic acid; and other carboxylic acids, such as phenylacetic acid, hydratropic acid, hydrocinnamic acid, mandelic acid, phenylsuccinic acid, atropic acid, cinnamic acid, methyl cinnamate, benzyl cinnamate, cinnamylideneacetic acid, coumaric acid and umbellic acid.

Color Filter and Production Method Thereof

The color filter of the present invention will be described in detail with reference to the production process thereof.

In the process for producing a color filter of the present invention, a color filter can be produced by using the negative dye-containing curable composition of the present invention as described above.

The negative dye-containing curable composition is coated onto a substrate by a coating method, such as spin coating, flow coating and roll coating, to form a radiation sensitive composition layer, which is then exposed through a prescribed mask pattern, followed by being developed with a developer, to form a negative colored pattern (image forming step). The process may further contain, depending on necessity, a curing step for curing the thus formed colored pattern by heating and/or exposure. Exposure by using the aforementioned stepper exposure is preferred when the negative dye-containing curable composition being exposed.

The color filter comprising desired hues may be produced by repeating the aforementioned image forming steps (and curing step, if necessary) by the number of the hues. As for light or radiation to be used on this occasion, ultraviolet light, particularly, a g ray, an h ray, an i ray or the like is favorably used.

Examples of the substrate include soda glass, PYREX™ (R) glass and quartz glass, which are used in a liquid crystal display device or the like, those having a transparent electroconductive film adhered, and a photoelectric conversion element substrate, such as a silicon substrate, and a complementary metallic oxide semiconductor (CMOS), which are used in a solid state image sensing device or the like. There are some cases where black stripes for separating pixels are formed on the substrate.

An undercoating layer may be provided, depending on necessity, on the substrate for improvement of adhesion to the upper layer, prevention of diffusion of substances, and planarization of the surface of the substrate.

The developer may be any one that has such a formulation that dissolves an uncured part of the dye-containing curable composition of the present invention but does not dissolve a cured part thereof. Specific examples thereof include a combination of various kinds of organic solvents and an alkali aqueous solution. Examples of the organic solvent include those having been described for preparation of the dye-containing curable composition of the present invention.

Preferred examples of the alkali aqueous solution include alkali aqueous solutions obtained by dissolving such an alkali compound to a concentration of 0.001 to 10% by mass, and preferably from 0.01 to 1% by mass, as sodium hydroxide, potassium hydroxide, sodium carbonate, sodium silicate, sodium metasilicate, aqueous ammonia, ethylamine, diethylamine, dimethylmethanolamine, tetramethylammonium hydroxide, tetraethylammonium hydroxide, choline, pyrrole, piperidine and 1,8-diazabicyclo-(5.4.0)-7-undecene. In the case where a developer containing the alkali aqueous solution is used, the layer thus developed is generally washed with water.

The color filter of the present invention can be used in a liquid crystal display (LCD) or a solid state image pick-up element such as CCD or CMOS. The color filter is suitable for a high resolution CCD element or CMOS having 1,000,000 or more pixels. The color filter of the present invention may be used by being interposed between light-receiving portions of the pixels constituting the CCD and micro-lenses for converging light.

### EXAMPLES

While the present invention is described in detail with reference to embodiments, the invention is not restricted thereto, so long as it does not depart from the scope and spirit of the present invention. Further, all “parts” as used in the examples are by mass, unless otherwise stated.

### Example 1

1) Preparation of the Negative Dye-Containing Curable Composition

Compounds in a composition as described below were mixed and dissolved, to thereby prepare a negative dye-containing curable composition of the present invention. The ratio [y/x] of the mass of the radical-polymerizable monomer (monomer A; y) to the mass of the alkali-soluble binder (resin A; x) is 5.0.

[Composition]

| | | |
|---|---|---|
| Ethyl lactate | 80.0 | parts |
| Resin A | 2.08 | parts |
| (alkali-soluble binder; Allyl methacrylate/methacrylic | | |
| acid copolymer (molar ratio of 80/20)) | | |
| Monomer A | 10.42 | parts |
| (radical-polymerizable monomer; dipentaerythritol | | |
| hexaacrylate) | | |
| Photopolymerization initiator | 1.5 | part |
| (trade name: TAZ-107; manufactured by Midori Kagaku | | |
| Co., Ltd.) | | |
| Organic solvent-soluble dye | 6.0 | parts |
| (Valifast yellow 1101) | | |

2) Preparation of Glass Substrate Provided with an Undercoat Layer

A glass substrate (trade name Corning 1737, manufactured by Corning, Incorporated) was ultrasonically washed in an aqueous 1% NaOH solution, then washed with water, and dehydration baked (at 200° C. for 30 minutes). Next, A resist solution (trade name: CT-2000L; manufactured by Fuji Film Arch Co., Ltd.) was applied onto the glass substrate washed with water by using a spin coater such that the resultant film has a thickness of 2 μm. After such application, the glass substrate was dried for one hour at 220° C. to form a cured film (undercoat layer) on the glass substrate.

3) Exposure and Development of Negative Dye-Containing Curable Composition (Image Forming Step)

The negative dye-containing curable composition which had been obtained in 1) was applied on the glass substrate provided with an undercoat layer which had been obtained in 2) by using a spin coater such that the resultant film has a thickness of 1 μm and, then, pre-baked for 120 seconds at 100° C.

### Examples 2 to 8

Negative dye-containing curable compositions of the examples were prepared in the same way as Example 1, except for the changes in the compositions as shown below in Table 1-1. Subsequently, samples of the Examples were prepared in the same way as Example 1 using the respective negative dye-containing curable compositions. The ratio of (y/x), the mass of the radical-polymerizable monomer (y) to the mass of the alkali-soluble binder (y) is shown in Table 1-1 below.

### Example 9

Negative dye-containing curable composition of Example 9 was prepared in the same way as Example 7, except for changing photopolymerization initiator from the “TAZ-107” to “Oxime A”. Subsequently, a sample of the Example 9 was prepared in the same way as Example 7 using the negative dye-containing curable composition of Example 9. The ratio of (y/x), the mass of the radical-polymerizable monomer (y) to the mass of the alkali-soluble binder (y) is shown in Table 1-1 below.

### Example 10

Negative dye-containing curable composition of Example 10 was prepared in the same way as Example 8, except for changing photopolymerization initiator from the “TAZ-107” to “Oxime A”. Subsequently, a sample of the Example 10 was prepared in the same way as Example 8 using the negative dye-containing curable composition of Example 10. The ratio of (y/x), the mass of the radical-polymerizable monomer (y) to the mass of the alkali-soluble binder (y) is shown in Table 1-2 below.

### Example 11

Negative dye-containing curable composition of Example 11 was prepared in the same way as Example 3, except for changing photopolymerization initiator from the “TAZ-107” to “Oxime A”. Subsequently, a sample of the Example 11 was prepared in the same way as Example 3 using the negative dye-containing curable composition of Example 11. The ratio of (y/x), the mass of the radical-polymerizable monomer (y) to the mass of the alkali-soluble binder (y) is shown in Table 1-2 below.

### Example 12

Negative dye-containing curable composition of Example 12 was prepared in the same way as Example 4, except for changing photopolymerization initiator from the “TAZ-107” to “Oxime A”. Subsequently, a sample of the Example 12 was prepared in the same way as Example 4 using the negative dye-containing curable composition of Example 12. The ratio of (y/x), the mass of the radical-polymerizable monomer (y) to the mass of the alkali-soluble binder (y) is shown in Table 1-2 below.

### Example 13

Negative dye-containing curable composition of Example 13 was prepared in the same way as Example 1, except for changing photopolymerization initiator from the “TAZ-107” to “Oxime A”. Subsequently, sample of the Example 13 was prepared in the same way as Example 1 using the negative dye-containing curable composition of Example 13. The ratio of (y/x), the mass of the radical-polymerizable monomer (y) to the mass of the alkali-soluble binder (y) is shown in Table 1-2 below.

### Example 14

Negative dye-containing curable composition of Example 14 was prepared in the same way as Example 2, except for changing photopolymerization initiator from the “TAZ-107” to “Oxime A”. Subsequently, a sample of the Example 14 was prepared in the same way as Example 2 using the negative dye-containing curable composition of Example 14. The ratio of (y/x), the mass of the radical-polymerizable monomer (y) to the mass of the alkali-soluble binder (y) is shown in Table 1-2 below.

### Comparative Example 1 to 3

Negative dye-containing curable compositions of the Comparative Examples were prepared in the same way as Example 1, except for the changes in the compositions as shown below in Table 1-2. Subsequently, samples of the Comparative Examples were prepared in the same way as Example 1 using the respective negative dye-containing curable compositions. The ratio of (y/x), the mass of the radical-polymerizable monomer (y) to the mass of the alkali-soluble binder (y) is shown in Table 1-2 below.

4) Evaluation

(1) Sensitivity

To the samples formed in the examples and comparative examples, light having a wavelength of 365 nm was irradiated on the coating film by using an i-ray stepper exposure device and changing the exposure amount, to thereby perform exposure through a height 2 μm×width 2 μm mask. After the exposure, the film was developed for 60 seconds at 23° C. by using a developer (trade name; CD-2000; manufactured by Fuji Film Arch Co., Ltd.). Subsequently, coating film was rinsed with running water for 20 seconds, subjected to spray drying, to thereby obtain a pattern image. The image formation was checked using the usual methods of an optical microscope and examination of SEM photographs.

In this case, the appropriate exposure amount is the exposing amount such that the ratio of a pixel pattern of height 2 μm×width 2 μm to that of the spacing between the pattern is 1:1. This exposure amount is taken as the sensitivity. A low value, indicating a high sensitivity, is preferable. The results are shown in the Table 1-1 and 1-2 below.

(2) Profile of Pattern

In (1) above, for a pixel pattern, formed with an appropriate exposure amount, an SEM image of a cross section was examined. Here, the evaluation of a good rectangular profile was designated A, a slightly round top contour was evaluated as B, and a completely rounded top profile (round head) as C. The results are shown in Table 1-1 and 1-2 below.

TABLE 1-1

| | | Radical- | | | | Mass | | Profile |
|---|---|---|---|---|---|---|---|---|
| | Alkali-soluble | polymerizable | Organic | Photopolymerization | | ratio | | of |
| | binder (x) | monomer(y) | solvent-soluble dye | initiator | Organic solvent | (y/x) | Sensitivity | pattern |
| Example 1 | Resin A | Monomer A | Valifast Yellow 1101 | TAZ-107 | Ethyl lactate | 5 | 850 | A |
| | (2.08) | (10.42) | (6.0) | (1.5) | (80.0) | | | |
| Example 2 | Resin A | Monomer A | Valifast Yellow 1101 | TAZ-107 | Ethyl lactate | 5 | 1200 | A |
| | (1.49) | (7.44) | (10.0) | (1.07) | (80.0) | | | |
| Example 3 | Resin A | Monomer A | Valifast Yellow 1101 | TAZ-107 | Ethyl lactate | 10 | 700 | A |
| | (1.13) | (11.25) | (6.0) | (1.62) | (80.0) | | | |
| Example 4 | Resin A | Monomer A | Valifast Yellow 1101 | TAZ-107 | Ethyl lactate | 10 | 1050 | A |
| | (0.80) | (8.04) | (10.0) | (1.16) | (80.0) | | | |
| Example 5 | Resin A | Monomer A | Valifast Yellow 1101 | TAZ-107 | Ethyl lactate | 100 | 550 | A |
| | (0.12) | (12.13) | (6.0) | (1.75) | (80.0) | | | |
| Example 6 | Resin A | Monomer A | Valifast Yellow 1101 | TAZ-107 | Ethyl lactate | 96 | 850 | A |
| | (0.09) | (8.67) | (10.0) | (1.25) | (80.0) | | | |
| Example 7 | Resin A | Monomer A | Valifast Yellow 1101 | TAZ-107 | Ethyl lactate | 1019 | 350 | A |
| | (0.012) | (12.23) | (6.0) | (1.76) | (80.0) | | | |
| Example 8 | Resin A | Monomer A | Valifast Yellow 1101 | TAZ-107 | Ethyl lactate | 970 | 500 | A |
| | (0.009) | (8.73) | (10.0) | (1.26) | (80.0) | | | |
| Example 9 | Resin A | Monomer A | Valifast Yellow 1101 | Oxime A | Ethyl lactate | 1019 | 250 | A |
| | (0.012) | (12.23) | (6.0) | (1.76) | (80.0) | | | |

TABLE 1-2

| | | Radical- | | | | Mass | | Profile |
|---|---|---|---|---|---|---|---|---|
| | Alkali-soluble | polymerizable | Organic | Photopolymerization | | ratio | | of |
| | binder (x) | monomer(y) | solvent-soluble dye | initiator | Organic solvent | (y/x) | Sensitivity | pattern |
| Example 10 | Resin A | Monomer A | Valifast Yellow 1101 | Oxime A | Ethyl lactate | 970 | 350 | A |
| | (0.009) | (8.73) | (10.0) | (1.26) | (80.0) | | | |
| Example 11 | Resin A | Monomer A | Valifast Yellow 1101 | Oxime A | Ethyl lactate | 10 | 500 | A |
| | (1.13) | (11.25) | (6.0) | (1.62) | (80.0) | | | |
| Example 12 | Resin A | Monomer A | Valifast Yellow 1101 | Oxime A | Ethyl lactate | 10 | 850 | A |
| | (0.80) | (8.04) | (10.0) | (1.16) | (80.0) | | | |
| Example 13 | Resin A | Monomer A | Valifast Yellow 1101 | Oxime A | Ethyl lactate | 5 | 700 | A |
| | (2.08) | (10.42) | (6.0) | (1.5) | (80.0) | | | |
| Example 14 | Resin A | Monomer A | Valifast Yellow 1101 | Oxime A | Ethyl lactate | 5 | 1000 | A |
| | (1.49) | (7.44) | (10.0) | (1.07) | (80.0) | | | |
| Comparative | Resin A | Monomer A | Valifast Yellow 1101 | TAZ-107 | Ethyl lactate | 1.5 | 1600 | C |
| example 1 | (5.16) | (7.73) | (6.0) | (1.1) | (80.0) | | | |
| Comparative | Resin A | Monomer A | Valifast Yellow 1101 | TAZ-107 | Ethyl lactate | 1.5 | not formed | |
| example 2 | (3.68) | (5.52) | (10.0) | (0.8) | (80.0) | | | |
| Comparative | Resin A | Monomer A | Valifast Yellow 1101 | TAZ-107 | Ethyl lactate | 4.5 | 2500 | B |
| example 3 | (1.63) | (7.3) | (10.0) | (1.05) | (80.0) | | | |

In table 1-1 to 1-2;
Resin A : Allyl methacrylate/methacrylic acid copolymer (molar ratio of 80/20))
Monomer A: dipentaerythritol hexaacrylate
Oxime A: 2-(o-benzoyloxime)-1-[4-(phenylthio)phenyl]-1,2-octanedione

In Table 1-1 and 1-2 above, when the mass ratio [y/x], of the mass [y] of radical-polymizerable monomer/the mass [x] of the alkali-soluble binder, is 5 or above as in the Examples, it is clear that the sensitivity is high and the profile is good. In comparison, it is clear that in the Comparative Examples where the value of the mass ratio (y/x) is less than 5 the sensitivity dramatically reduces.

Also, from the above Table 1-1 and 1-2 it can be seen that when an oxime type photopolymerization initiator is used, rather than a triazime type photopolymerization initiator, the sensitivity is superior. In addition to this, it is clear that the problem of the generation of chlorine gas with triazime type photopolymerization initiators does not occur at all.

As seen above, by the invention it is possible to provide a negative dye-containing curable composition which can provide high sensitivity and the ability to form rectangular patterns (in particular when the patterns are formed by exposure using stepper exposure). Also, by the invention it is possible to provide a color filter, together with a manufacturing method thereof, which is superior in pattern formability and has high cost performance.

1. A negative dye-containing curable composition, comprising (A) an alkali-soluble binder, (B) an organic solvent-soluble dye, (C) a photopolymerization initiator and (D) a radical-polymerizable monomer, wherein:
the ratio [y/x] of the mass of (D) the radical-polymerizable monomer [y] to the mass of (A) the alkali-soluble binder [x] is greater than or equal to 5.

2. The negative dye-containing curable composition as set forth in claim 1, wherein the ratio [y/x] of the mass of (D) the radical-polymerizable monomer [y] to the mass of (A) the alkali-soluble binder [x] is greater than or equal to 100.

3. The negative dye-containing curable composition as set forth in claim 1, wherein the ratio [y/x] of the mass of (D) the radical-polymerizable monomer [y] to the mass of (A) the alkali-soluble binder [x] is greater than or equal to 1000.

4. The negative dye-containing curable composition as set forth in claim 1, wherein a content of (B) the an organic solvent-soluble dye is in the range, based on total solid components, of from 0.5% by mass to 90% by mass.

5. The negative dye-containing curable composition as set forth in claim 1, wherein a content of (B) the organic solvent-soluble dye is in the range, based on total solid components, of from 40% by mass to 90% by mass.

6. The negative dye-containing curable composition as set forth in claim 1, wherein (C) the photopolymerization initiator is an oxime type compound

7. The negative dye-containing curable composition as set forth in claim 1, wherein (C) the photopolymerization initiator is at least one compound selected from the group consisting of 2-(o-benzoyloxime)-1-[4-(phenylthio)phenyl]-1,2-octanedione and 1-(o-acetyloxime)-1-[9-ethyl-6-(2-methylbenzoyl)-9H-carbazole-3-yl] ethanone.

8. A color filter, produced by using a negative dye-containing curable composition comprising (A) an alkali-soluble binder, (B) an organic solvent-soluble dye, (C) a photopolymerization initiator and (D) a radical-polymerizable monomer, wherein:
the ratio [y/x] of the mass of (D) the radical-polymerizable monomer [y] to the mass of (A) the alkali-soluble binder [x] is greater than or equal to 5.

9. The color filter as set forth in claim 8, wherein the ratio [y/x] of the mass of (D) the radical-polymerizable monomer [y] to the mass of (A) the alkali-soluble binder [x] is greater than or equal to 100.

10. The color filter as set forth in claim 8, wherein the ratio [y/x] of the mass of (D) the radical-polymerizable monomer [y] to the mass of (A) the alkali-soluble binder [x] is greater than or equal to 1000.

11. The color filter as set forth in claim 8, wherein a content of (B) the organic solvent-soluble dye is in the range, based on total solid components, of from 0.5% by mass to 90% by mass.

12. The color filter as set forth in claim 8, wherein a content of (B) the organic solvent-soluble dye is in the range, based on total solid components, of from 40% by mass to 90% by mass.

13. The color filter as set forth in claim 8, wherein (C) the photopolymerization initiator is an oxime type compound.

14. The color filter n as set forth in claim 8, wherein (C) the photopolymerization initiator is at least one compound selected from the group consisting of 2-(o-benzoyloxime)-1-[4-(phenylthio) phenyl]-1,2-octanedione and 1-(o-acetyloxime)-1-[9-ethyl-6-(2-methylbenzoyl)-9H-carbazole-3-yl] ethanone.

15. A method of producing a color filter, comprising:
applying the negative dye-containing curable composition as set forth in claim 1 onto a substrate;
exposing the applied negative dye-containing curable composition through a mask; and
developing the exposed negative dye-containing curable composition to form a pattern.
